(19) United States
(12) Patent Application Publication
(10) Pub. No.: US 2026/0231830 A1
(43) Pub. Date: Aug. 6, 2026

(54) MULTI-DIE BRIDGE ASSEMBLIES AND METHODS FOR THREE-DIMENSIONAL PACKAGING

(71) Applicant: Intel Corporation, Santa Clara, CA (US)

(72) Inventors: Jeremy D. Ecton, Gilbert, AZ (US); Minglu Liu, Chandler, AZ (US); Mohamed R. Saber, College Station, TX (US); Brandon Christian Marin, Gilbert, AZ (US); Bohan Shan, Chandler, AZ (US); Ravindranath V. Mahajan, Chandler, AZ (US); Benjamin T. Duong, Phoenix, AZ (US); Gang Duan, Chandler, AZ (US); Srinivas V. Pietambaram, Chandler, AZ (US); Suddhasattwa Nad, Chandler, AZ (US); Kristof Darmawikarta, Chandler, AZ (US); Zhiguo Qian, Chandler, AZ (US); Rahul Manepalli, Chandler, AZ (US)

(21) Appl. No.: 19/631,770

(22) Filed: Mar. 27, 2026

Related U.S. Application Data
(63) Continuation of application No. 18/582,203, filed on Feb. 20, 2024.

(51) Int. Cl. H10W 90/00; H10B 80/00; H10W 20/20; H10W 42/00; H10W 70/60; H10W 70/63; H10W 70/65; H10W 70/685; H10W 70/692; H10W 72/90; H10W 74/15

(52) U.S. Cl. CPC H10W 90/00; H10B 80/00; H10W 20/20; H10W 42/121; H10W 70/611; H10W 70/635; H10W 70/65; H10W 70/685; H10W 70/692; H10W 72/952; H10W 74/15; H10W 90/724; H10W 90/732; H10W 90/734; H10W 90/792

(57) ABSTRACT

Multi-die bridge assemblies and methods for three-dimensional packaging. The architectures assemble a bridge component with two or more integrated circuit die to thereby create a multi-die (MD) bridge assembly. The means for attaching the bridge component to the dies can be hybrid bonding, solder bumps, thermal compression bonding, or a combination thereof. The created MD bridge assembly can be subjected to performance testing prior to attachment to a substrate. Attaching the MD bridge assembly to the substrate can include fitting the bridge component portion into a cavity in the substrate and attaching the bridge component to a cavity floor with another plurality of attachment options.

### CROSS-REFERENCE TO RELATED APPLICATIONS

This application is a continuation of U.S. patent application Ser. No. 18/582,203, filed on Feb. 20, 2024, the entire contents of which is hereby incorporated by reference herein.

### BACKGROUND

There is an ongoing push to improve bump density, power efficiency, speed and bandwidth in semiconductor packaging. However, available methodologies and architectures that support 3D packaging present technical challenges in fabrication and higher cost. Accordingly, improved architectures and methods for three-dimensional (3D) semiconductor packaging are desired.

### BRIEF DESCRIPTION OF THE DRAWINGS

FIG. 1 is a simplified cross-sectional illustration of a multi-die bridge assembly including a bridge component and two integrated circuit dies, in accordance with various embodiments.

FIG. 2A depicts FIG. 1 in which a bridge component is hybrid bonded to the two integrated circuit dies, in accordance with various embodiments.

FIG. 2B depicts FIG. 1 in which a bridge component is solder bonded to the two integrated circuit dies, in accordance with various embodiments.

FIG. 3A depicts FIG. 1 in which another bridge component is hybrid bonded to the two integrated circuit dies, in accordance with various embodiments.

FIG. 3B depicts FIG. 1 in which another bridge component is solder bonded to the two integrated circuit dies, in accordance with various embodiments.

FIG. 4A illustrates a mold encapsulation over the lower surface/backside of the integrated circuit components in a hybrid bonded bridge embodiment, in accordance with various embodiments.

FIG. 4B illustrates a mold encapsulation over the lower surface/backside of the integrated circuit components in a solder bonded bridge embodiment, in accordance with various embodiments.

FIG. 5A illustrates a multi-die bridge assembly with ball pitch solder pads, in accordance with various embodiments.

FIG. 5B illustrates a multi-die bridge assembly configured for hybrid bonding in a cavity, with ball pitch solder pads for the two integrated circuit dies, in accordance with various embodiments.

FIG. 6A illustrates a multi-die bridge assembly that includes a glass frame, in accordance with various embodiments.

FIG. 6B illustrates an inverted multi-die bridge assembly, with the bridge component on the top and with the lower surfaces or backsides of the two integrated circuit dies prepped for a solder attach, in accordance with various embodiments.

FIG. 7 illustrates a substrate with a cavity for bonding to a multi-die bridge assembly, in accordance with various embodiments.

FIG. 8 illustrates the substrate of FIG. 7 with an embodiment of the multi-die bridge assembly solder attached in the cavity, in accordance with various embodiments.

FIG. 9 illustrates the substrate of FIG. 7 with an embodiment of the multi-die bridge assembly hybrid bonded in the cavity, in accordance with various embodiments.

FIG. 10 illustrates a substrate without a cavity, with the multi-die bridge assembly inverted and solder bonded on an upper surface, in accordance with various embodiments.

FIG. 11 illustrates an example method for a multi-die bridge assembly, in accordance with various embodiments.

FIG. 12 is a top view of a wafer and dies that may be included in a microelectronic assembly, in accordance with any of the embodiments disclosed herein.

FIG. 13 s a simplified cross-sectional side view showing an implementation of an integrated circuit on a die that may be included in various embodiments, in accordance with any of the embodiments disclosed herein.

FIG. 14 is a cross-sectional side view of a microelectronic assembly that may include any of the embodiments disclosed herein.

FIG. 15 is a block diagram of an example electrical device that may include any of the embodiments disclosed herein.

### DETAILED DESCRIPTION

There is an increased focus on three-dimensional (3D) semiconductor packaging architectures and methodologies to deliver significant improvements in bump density, power efficiency, speed and bandwidth. Many proposed solutions rely on die to die (D2D) and/or die to wafer (D2 W) bonding methods and architectures. However, many available D2D and D2 W methods and architectures face fabrication challenges and higher costs.

For example, in a D2D or D2 W assembly, multiple disparate dies and varying pitch dimensions and bonding types (e.g., solder and hybrid bonding) may need to be integrated. One technical challenge to D2D and D2 W bonding is the complexity and high cost of copper-to-copper bonding technologies needed.

Another technological challenge is the implementation and performance of a bridge component. Bridge components are used to operationally couple disparate integrated circuit dies and often incorporate multiple pitch and bonding applications. Passive bridge components only provide electrical pathways or signal routes between dies on one surface. Passive bridge components are easier to fabricate and lower cost but cannot achieve the maximum current (Imax) that many applications require. Active bridge components often include through silicon vias (TSVs) to route power and ground between surfaces, and thereby improve Imax; however, technical challenges, such as drilling, alignment, cavity filling and soldering remain. Accordingly, continued improvements to methods and architectures for 3D semiconductor packaging are desired.

Embodiments described herein provide a technical solution to these technical challenges in the form of multi-die bridge assemblies and methods for 3D packaging. Some of the embodiments employ hybrid bonding (HB), also referred to as hybrid bonding interconnect (HBI) or direct bond interconnect (DBI). HBI is a packaging technology that involves bringing together the surfaces of two semiconductor devices under applied pressure and/or at elevated temperature, generally as a die stacking solution, resulting in dielectric-to-dielectric bonding and metal-to-metal bonding. HBI advantageously enables “small” pitches (defined herein as a pitch less than 10 microns+/−10%, and in some cases, the pitch is less than 1 micron+/−10%). However, for a variety of reasons, many substrates remain solder-attach components, having solder-based interconnects for electrical communication with IC dies. Therefore, some of the embodiments of the multi-die bridge components described hereinbelow integrate hybrid bonding interconnect (HBI) components with solder-attach components. These concepts are developed in more detail below.

Example embodiments are hereinafter be described in conjunction with the following drawing figures, wherein like numerals denote like elements. Unless otherwise stated, figures are not necessarily to scale but may be relied on for spatial orientation and relative positioning of features. As may be appreciated, certain terminology, such as “ceiling” and “floor”, as well as “upper,”, “uppermost”, “lower,” “above,” “below,” “bottom,” and “top” refer to directions based on viewing the Figures to which reference is made. Further, terms such as “front,” “back,” “rear,”, “side”, “vertical”, and “horizontal” may describe the orientation and/or location of portions of the component within a consistent but arbitrary frame of reference which is made clear by reference to the text and the associated Figures describing the component under discussion. Such terminology may include the words specifically mentioned above, derivatives thereof, and words of similar import.

As used herein, the term “adjacent” refers to layers or components that are in direct physical contact with each other, with no layers or components in between them. For example, a layer X that is adjacent to a layer Y refers to a layer that is in direct physical contact with layer Y. In contrast, as used herein, the phrase(s) “located on” (in the alternative, “located under,” “located above/over,” or “located next to,” in the context of a first layer or component located on a second layer or component) includes (i) configurations in which the first layer or component is directly physically attached to the second layer (i.e., adjacent), and (ii) component and configurations in which the first layer or component is attached (e.g. coupled) to the second layer or component via one or more intervening layers or components.

The following detailed description is not intended to limit the application and use of the disclosed technologies. It may be evident that the novel embodiments can be practiced without every detail described herein. For the sake of brevity, well-known structures and devices may be shown in block diagram form to facilitate a description thereof.

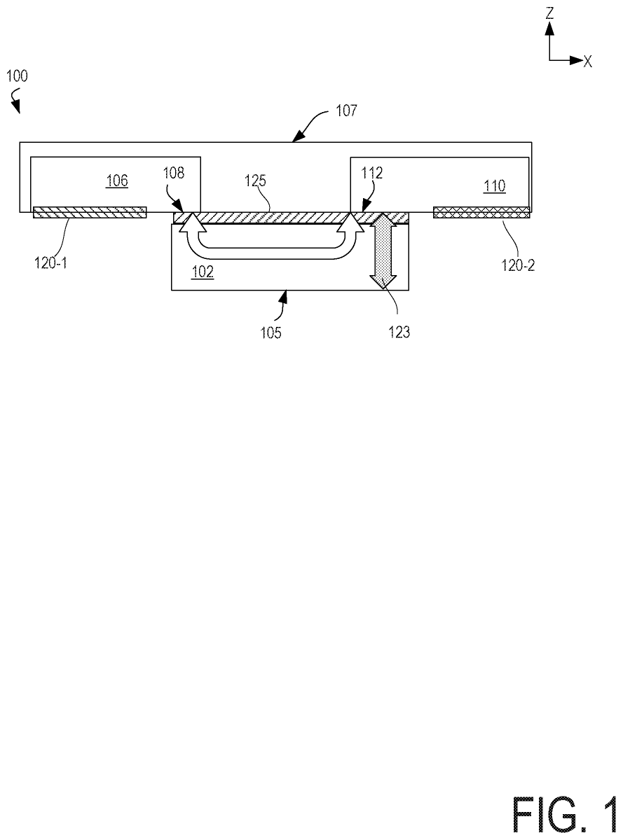

FIGS. 1-6B provide a variety of non-limiting examples of embodiments of a multi-die bridge assembly for 3D packaging. Many of the objects in the images are repeated, and like objects are intended to perform the same function or be the same feature across images, whether labeled or not.

FIG. 1 is a simplified cross-sectional illustration of a multi-die bridge assembly 100 comprising a bridge component 102 and two integrated circuit dies die 106 (IC 1) and die 110 (IC 2). The die 106 and 110, may be unpackaged integrated circuit die, and may alternatively be referred to as chips, chiplets, chip complexes, or chiplet complexes. While the terms die, chip, and chiplet may be used interchangeably, the term chiplet is sometimes used to refer to an integrated circuit die that implements a subset of the functionality of a larger integrated circuit component. Although the illustration depicts the chiplets as having uniform dimensions, in practice, chiplet dimensions (lateral dimensions, as well as thickness) and shape can vary among chiplets; moreover, the chiplets may vary by type/functionality (e.g., compute, memory, I/O, power management (controlling the delivery of power and/or providing power to components)). Furthermore, multi-die bridge assembly 100 can have any shape, such as a substantially square shape, substantially rectangular shape, or substantially circular shape.

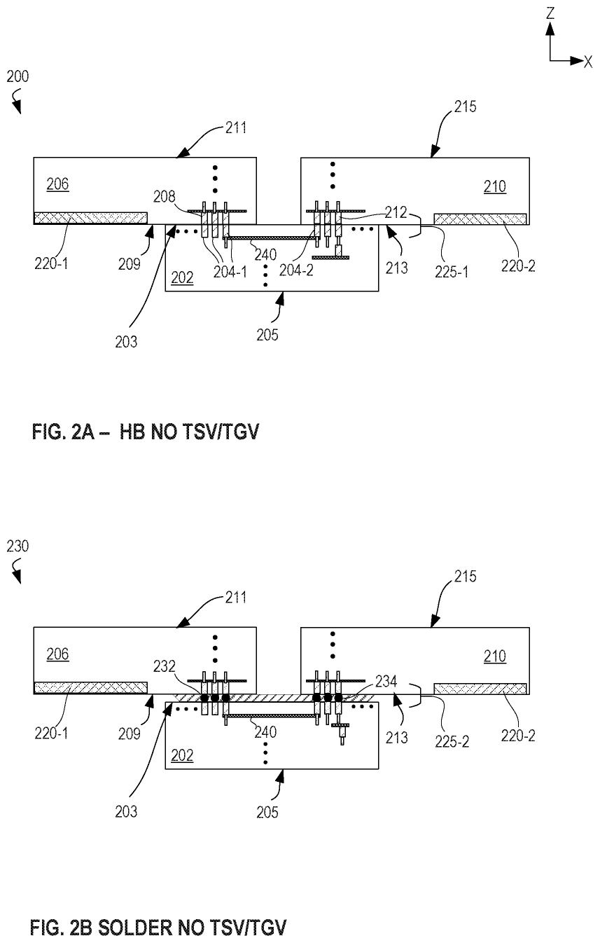

Die 106 and die 110 are stabilized within an encapsulant 124. The encapsulant 124 can comprise a molding compound, dielectric materials, metal, ceramic, plastic, or a combination thereof. Although the encapsulant was omitted from the illustrations in FIGS. 2, 3, and 4 to simplify feature discussions, in practice, those embodiments would have an encapsulant.

The multi-die bridge assembly 100 has a bottom surface 105/205/305/405 (in the drawing) and a top surface 107. Die 106/206/306/406/506/606/has a region of input/output contacts 120-1 (I/O 120-1) (also I/O 220-1/320-1/420-1/520-1/620-1) that are to interface with a substrate, generally arranged at a bump pitch that is larger than a hybrid bond interconnect (HBI) bump pitch. In a non-limiting example, a bump pitch may be 110-86 microns BP for the first IC and 110-95 microns for the second IC. In other examples, the solder bumps are greater than or equal to 25 microns and the HBI bump pitch is less than 25 microns. In some embodiments, HBI bumps can be 10 microns, in other embodiments, the HBI bumps can be 2 microns. Die 110/210/310/410/510/610 similarly has a region of input/output contacts 120-2 (I/O 120-2) (also I/O 220-2/320-2/420-2/520-2/620-2) that are to interface with the substrate, generally arranged at the bump pitch. In some embodiments, the I/O 120-1 and I/O 120-2 include solder bumps attached thereto.

The bridge component 102/202/302/402/502/602 is to provide one or more electronic pathways between die 106 and die 110, as indicated with the curved cartoon arrow. The bridge component 102/202/302/402/502/602 may be embodied as a conventional silicon bridge, an organic bridge, a glass bridge, or some combination thereof. As used herein, a passive bridge component is limited to the electronic pathways between die 106 and die 110, whereas an active bridge component can comprise transistors, logic, and/or memory in addition to the electronic pathways. Electronic communication between die 106 and die 110 is facilitated through these electronic pathways in the bridge component 102/202/302/402/502/602 by a means for attachment 125. As is described in more detail below, the means for attachment can be solder bumps with solder material, hybrid bonding (HB), first level interconnect thermal compression bonding (TCB) micro ball, or plating.

The die 106 has I/O structures 108 on a first portion of its upper surface to communicate via the bridge component 102 to the die 110, and the die 110 has similar I/O structures 112 on first portion of its upper surface to communicate via the bridge component 102 to the die 106. The collective I/O structures to support the die-to-die (or, wafer-to-wafer) communication are referred to herein as the means for attachment 125. The means for attachment on the upper surface of the bridge component 102 are separated into a first portion for attaching to the first die 106 and a second portion for the second die 110. As may be appreciated, when the means for attachment is solder bumps, the I/O structures 108 and 112 and upper surface of the bridge component 102 are configured for solder bumps, when the means for attachment is hybrid bonding (HB), the I/O structures and upper surface of the bridge component 102 are configured for HB, etc. For the bridge components, when the means for attachment 125 is a solder bump or micro bump field 225-2/325-2/425-2, the solder bump pitch (BP) may be in a range of 45 microns plus or minus 10% to 55 microns plus or minus 10%. In other embodiments, the solder bump pitch can be in a range of 25-35 microns. When the means for attachment 125 is HBI, the HBI pitch on the bridge components 102 is smaller still, in a range of 1 to 10 microns.

The optional cartoon arrow 123 represents electronic pathways between a first surface 103 of the bridge component 102 and a second surface 105 of the bridge component 102. Optional cartoon arrow 123 generally represents a through-silicon via (TSV) or through-glass via (TGV) with a conductive material inside, for power and ground routing. In various embodiments, but not always, when optional cartoon arrow 123 is omitted, the bridge component 102 is a “passive bridge component.” Likewise, in various embodiments, but not always, when the bridge component 102 includes the optional cartoon arrow 123, the is an “active bridge component.” In practice, the optional cartoon arrow 123 is often used to enable power to be routed into the bridge component 102 from a source located at a bottom of a cavity in a substrate. The electrical pathways or routing indicated by optional cartoon arrow 123 reduces the number of substrate routing layers and can improve product yield.

FIG. 2A multi-die bridge assembly 200 depicts a bridge component 202 hybrid bonded to the two integrated circuit dies and FIG. 2B multi-die bridge assembly 230 depicts a bridge component 202 solder bonded to the two integrated circuit dies. Towards the top of the page are the lower surfaces of the die IC 1 and IC 2 (corresponding to top surface 107 in FIG. 1), because they have been flipped during fabrication. Die 106/206/306/406 has upper surface 209/309/409 and lower surface 211/311/411; die 110/210/310/410 has upper surface 213/313/413/513 and lower surface 215/315/415/515.

With a focus on FIG. 2A, when the means for attachment 125 is implemented as a hybrid bonding interface (HBI) 225-1, the die 106 and die 110 each include a HB surface. As mentioned, the dies 206/306/406/506/606 and 208/308/408/508/608 are flipped, so the HB surfaces appear as a lower surface of dies in the multi-die bridge assemblies.

The HB surface of die 206/306/406 is defined by hybrid bond contacts 208/308/408 surrounded by an insulating material (often, a dielectric material). The HB surface of die 210/310/410 is defined by hybrid bond contacts 212/312/412, surrounded by an insulating material (this does not have to be the same dielectric material as is used in die 206/306/406). Likewise, the bridge component 202/302/402 comprises an insulating material and defined by a first surface 203 and a second surface 205.

The insulating material in the bridge component, IC 1 and/or IC 2 may be any dielectric material, such as, a suitable nitride or oxide, such as silicon dioxide (SiO₂), carbon-doped silicon dioxide (C-doped SiO₂, also known as CDO or organosilicate glass, which is a material that comprises silicon, oxygen, and carbon), fluorine-doped silicon dioxide (F-doped SiO₂, also known as fluorosilicate glass, which is a material that comprises fluorine, silicon, and oxygen), hydrogen-doped silicon dioxide (H-doped SiO₂, which is a material that comprises silicon, oxygen, and hydrogen). In some embodiments, a dielectric layer comprises a photo-imageable dielectric (PID). In some embodiments, the dielectric layer comprises an Ajinomoto Build-Up film (often referred to as ABF), which is a material that comprises an organic resin matrix with different types of fillers (for example, silica fillers of different sizes, or hollow fillers of different sizes) to control the coefficient of thermal expansion (CTE) and/or electrical properties (e.g., the dielectric constant (Dk), and/or dissipation factor (insertion loss) (Df)).

In some embodiments, it is advantageous for the dielectric layer in the bridge component to have a CTE that matches that of integrated circuit dies (IC 1 and IC 2) (e.g., match the CTE of silicon) or to have a CTE that matches a substrate or PCB. In some embodiments, the dielectric material can have a CTE that is close (e.g., within 10%) to that of silicon. In other embodiments, the dielectric material can be any type of epoxy molding compound.

Returning to the discussion of the HB interface 225-1, the first die 106/206/306 comprises an upper surface 209/309/409 with an insulating material and a plurality of HB contacts therein, and the second die 210/310/410 comprises another insulating material with another plurality of HB contacts 212/312/412 therein. At the surface 209/309/409 and surface 213/313/413, the HB contacts are exposed, and the dielectric is exposed; in other words, at the HB surface(s) there is dielectric material adjacent to metal/Cu hybrid bond contacts. The HB contacts 208/308/408 and HB contacts 212/312/412 may be a metal and may comprise copper. In various embodiments, at least one hybrid bond contact 208/308/408 and at least one hybrid bond contact 212/312/412 is exposed at the HB interface 225-1.

When the means for attachment 125 is HB, as in HB interface 225-1, the first surface 203 comprises a plurality of HB contacts (first metal contacts 204/304/404) therein, the plurality of first metal contacts organized into a first area (first metal contacts 204-1/304-1/404-1) and a second area (second first metal contacts 204-2/304-2/404-2). As indicated in FIG. 1 with the cartoon arrow, the bridge component provides at least one electrical pathway 240/340/440/540/640 between a first first metal contact 204-1 in the first area and a second first metal contact 204-2 in the second area. The second surface 205 may be configured to attach to a substrate.

In multi-die bridge assembly 200, the die 206 is hybrid bonded to bridge component 202 and the die 210 is hybrid bonded to the bridge component 202, as shown. Accordingly, at the HB interface 225-1, insulating or dielectric material of die 106 and insulating or dielectric material of die 110 is bonded to the insulating or dielectric material of bridge component 202 (e.g., in a SEM image, one would see the dielectric material SiOx to SiOx, SiOxNy to SiOxNy, or the like) and HB contacts 208 are bonded to HB contacts 204-1 and HB contacts 212 are bonded to HB contacts 204-2. There is no solder material at this HB interface 225-1.

FIG. 2B has all the same components and objects as FIG. 2A, except for the implementation of the means for attachment 125. In FIG. 2B, the means for attachment is a solder bump or micro bump field 225-2/325-2/425-2. The first die 206/306/406 is solder attached to the bridge component 202/302/402 with solder bumps 232/332/432, and the second die 210/310/410 is solder attached to the bridge component 202/302/402 with solder bumps 234/334/434.

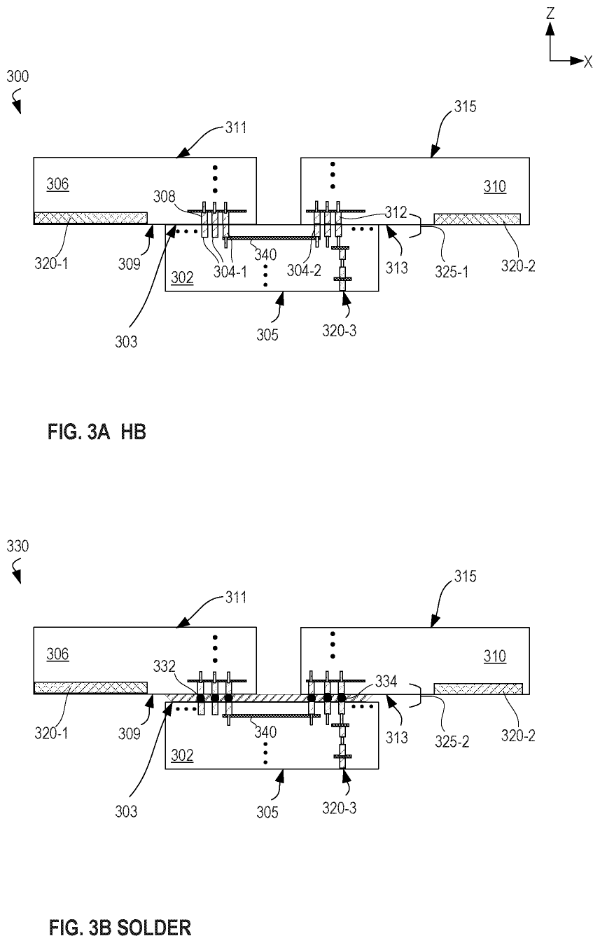

FIG. 3A multi-die bridge assembly 300 depicts a bridge component hybrid bonded to the two integrated circuit dies. FIG. 3A has the same components and objects as FIG. 2A, with the addition of at least one contact 320-3/420-3 on the second surface 305/405 that provides an electrical pathway to the first surface 303/403 (embodying FIG. 1, cartoon arrow 123). When assembled into a package with a substrate, power and ground may be routed through these electrical pathways from the second surface 305 to the integrated circuits in die 106 and die 110, respectively.

FIG. 3B multi-die bridge assembly 330 depicts a bridge component solder bonded to the two integrated circuit dies, in accordance with various embodiments. FIG. 3B has the same components and objects as FIG. 2B, with the addition of at least one contact 320-3 on the second surface 305 that provides an electrical pathway to the first surface 303.

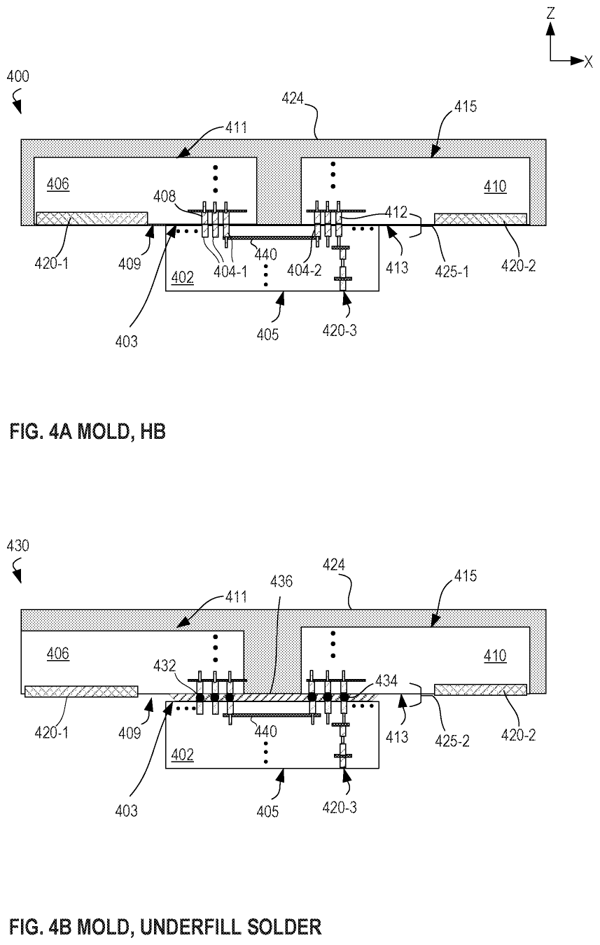

FIG. 4A multi-die bridge assembly 400 depicts the multi-die bridge assembly 300 with a mold encapsulation 424 over the lower surface/backside of the die 406 and die 410. As with FIG. 2A and FIG. 3A, the bridge component 402 is hybrid bonded to the die 406 and to the die 410. FIG. 4B multi-die bridge assembly 430 depicts the multi-die bridge assembly 330 with a mold encapsulation 424 over the lower surface/backside of the of the die 406 and die 410 in a solder bonded bridge component 402 embodiment, and in addition, shows an underfill 436 between the bridge component and the upper surfaces 409 and 413. The underfill surrounds the solder bumps 432 and 434. A variety of underfill materials can be used, generally they are non-conducting (electrically) and reduce thermomechanical stress. Underfill materials may take the form of a liquid pre-polymer with a filler such as silica, alumina, or boron nitride. The underfill can be cured to solidify it.

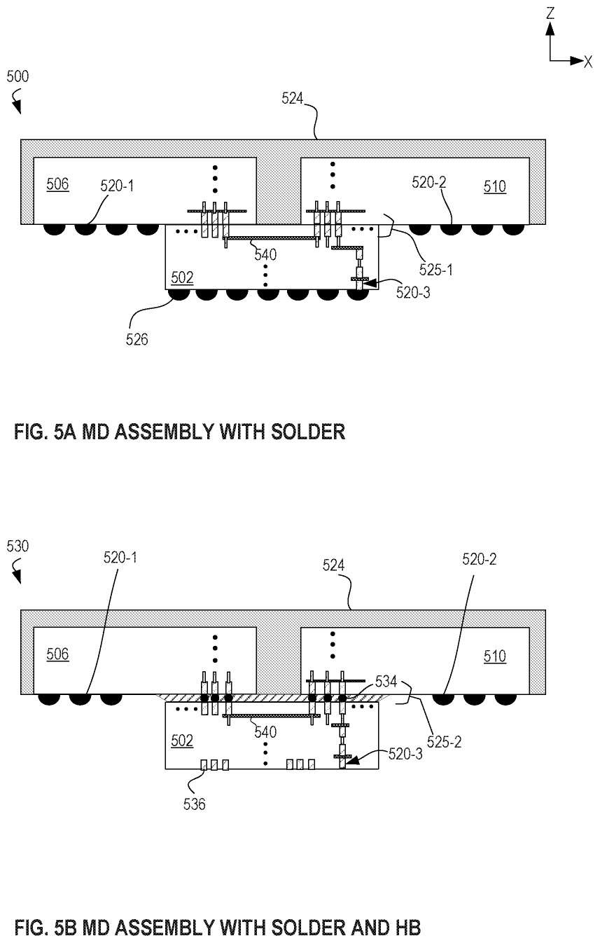

FIG. 5A and FIG. 5B provide two non-limiting examples of multi-die bridge assemblies 500 and 530, prepped for assembly onto a substrate. The depicted bridge component 502 is a bridge component with TSVs or TGVs. The multi-die bridge assembly 500 includes ball pitch solder pads 520-1 on the first die 506, ball pitch solder pads 520-2 on the second die 510, and ball pitch solder pads 526 on the second surface (“bottom” in the drawing, the portion that may fit into a cavity in a substrate) of the bridge component 502. FIG. 5B illustrates a multi-die bridge assembly 530 configured for hybrid bonding in a cavity (HB contacts 536), with ball pitch solder pads 520-1 and 520-2 configured for solder attaching the two integrated circuit dies to a substrate.

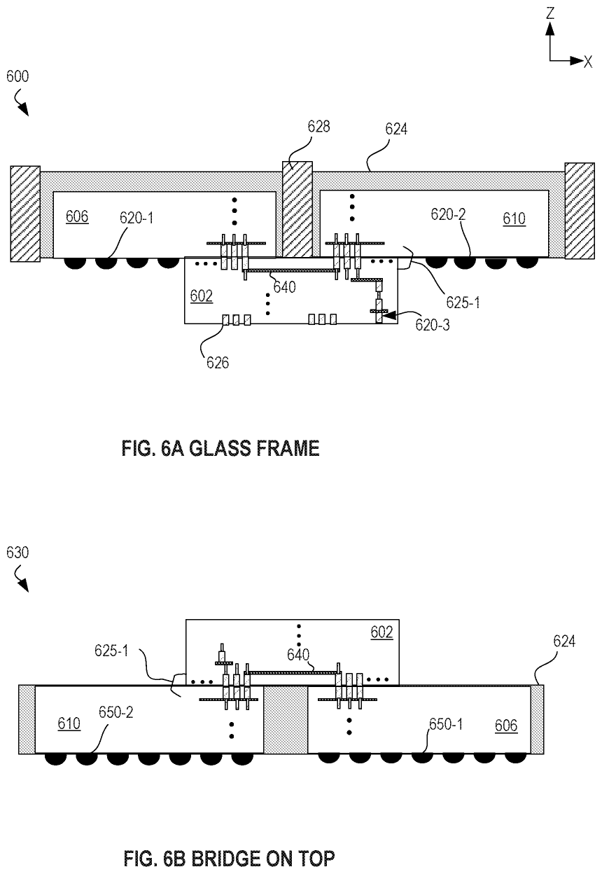

In FIG. 6A, embodiment 600 depicts embodiment 500 with the addition of a glass frame 628. In a plan view, the glass frame 628 may look like a glass ladder or a glass door with a couple of open windows or cavities therethrough. The glass frame (also referred to herein as a glass structure) is to provide structural stability for the die 606 and die 610. In the cavities in the glass structure, individual dies are located, and the dies are surrounded by the encapsulant 624.

In FIG. 6B, multi-die bridge assembly 630 embodiment illustrates that some applications may flip the multi-die bridge assembly 630 over, such that it is attached to a substrate on the lower or backsides of the die 106 and die 110 (solder bumps 650-2 on die 610 and solder bumps 650-1 on die 606).

The above is not an exhaustive list of combinations that can be found in the multi-die bridge component. Those with skill in the art will appreciate that additional multi-die bridge assembly embodiments, not illustrated, are supported based on figures and descriptions included herein. For example, see Table 1. In addition to the variations provided in table 1, embodiments may include the glass frame. Additionally, as part of a thermal management solution, a thermal conduction layer interface material (TIM) (not shown) may be located over the encapsulant and/or over the die 106/206/306/406/506/606 and die 110/210/310/410/510/610. The TIM can be any suitable material, such as a silver particle-filled thermal compound, thermal grease, phase change materials, indium foils, or graphite sheets. The thermal management solution can be a conformal solution that accommodates differences in heights of the integrated circuit dies for which the thermal management solution provides cooling. For example, a thermal management solution can comprise a substantially planar cooling component with TIMs of varying thickness between the cooling component and the integrated circuit dies. In another example, the cooling component is non-planar, and the profile of the cooling component can vary with the thickness of the integrated circuit dies for which the cooling component provides cooling. In such embodiments, the TIM can be of substantially uniform thickness between the cooling component and the integrated circuit dies of varying thicknesses. Thermal management solutions can also include an integrated heat spreader.

TABLE 1

| | | | | | No |
|---|---|---|---|---|---|
| | | | | TSV/TGV | TSV/TGV |
| | Bridge attach | | | Bridge | Bridge |
| | to Die 1 and | Die 1 attach | Die 2 attach | attach to | attach to |
| | Die 2 | to substrate | to substrate | substrate | substrate |
| Hybrid | Yes | Yes | Yes | Yes | No |
| bonding | | | | | |
| Solder bump | Yes - use S1 | Yes - use S2 | Yes - use S2 | Yes | No |
| with underfill | with melting | with MP less | with MP less | | |
| | point greater | than S1, | than S1, | | |
| | than S2, | examples | examples | | |
| | examples | tin/zinc, | tin/zinc, | | |
| | gold/tin, tin, | tin/silver, | tin/silver, | | |
| | etc. | tin/bismuth, | tin/bismuth, | | |
| | | etc. | etc. | | |
| Micro ball | Yes | Yes | Yes | Yes | No |
| Thermal | Yes | Yes | Yes | Yes | No |
| compression | | | | | |
| bonding with | | | | | |
| underfill | | | | | |
| paste | No | No | No | No | Yes |

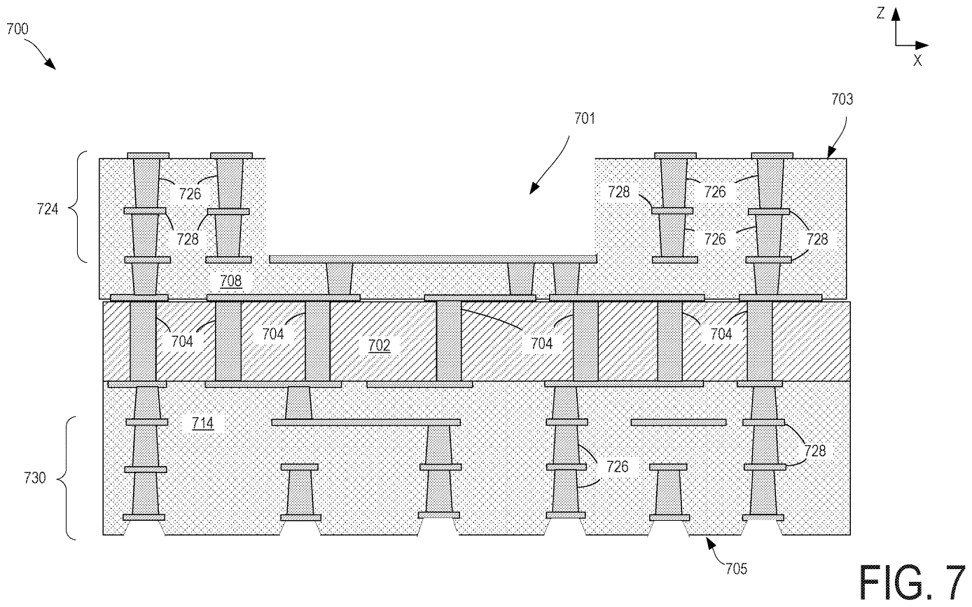

The multi-die (MD) assemblies can be attached to a substrate. With reference to FIGS. 7, 8, 9, and 10, this is described. FIG. 7 illustrates a substrate 700/870/970/1070 that includes one or more dielectric layers 724 with redistribution layers (RDL) conductive traces 728 patterned therein. Various embodiments of the substrate may also have a layer of glass 702/802/902/1002 or glass core and dielectric layers 730/830/930/1030 with RDL conductive traces and vias 726/728, 826/828, 926/928 and 1026/1028 patterned therein and located on a lower surface of a glass core 702/802/902/1002.

The dielectric layers 724 and 730 can be a suitable dielectric as described above. The conductive material used for conductive contacts, HB contacts (e.g., 208, 212, 204), and RDL traces and vias 728/728 may comprise a metal (e.g., copper, aluminum, nickel, cobalt, iron, tin, gold, silver, or combinations thereof) or another suitable conductive material.

Substrate 700 illustrates a layer of glass 702/802/902/1002 or glass core patterned with through-holes or multiple through-glass vias (TGVs) 704/804/904/1004. The layer of glass 702/830/930/1030 may comprise glass, (as used herein, glass can be an alkali-free alkaline earth boro-aluminosicilate glass, such as a glass comprising aluminum, oxygen, boron, silicon, and an alkaline-earth metal (e.g., beryllium, magnesium, calcium, strontium, barium, radium, such as a glass comprising SiO2, Al2O3, B2O3, and MgO), or a photosensitive glass (photomachineable or photostructurable glass). In some embodiments, a photosensitive glass can be a glass that belongs to the lithium-silicate family of glass (e.g., a glass comprising lithium, silicon, and oxygen) comprising metallic particles, such as gold, silver, or other suitable metallic particles. The layer of glass 702 or glass core may comprise multiple glass sheets bonded together with an adhesion layer. In various embodiments, e.g., in a substrate 700 with a Z height (in the drawing) in a range of about 10 millimeters (mm) to 500 mm, the layer of glass 702 may have a thickness (Z height) in a range of about 20 microns to about 1.5 millimeter, +/−10%. The TGVs 704 are volumes in which glass is removed and conductive materials are placed in the volumes, sufficient to enable electrical communication from an upper surface 703 to a lower surface. As illustrated in embodiment of substrate 700, the TGVs 704 are substantially perpendicular to an upper surface 703 of the layer of glass 702. In embodiments that manufacture a panel at a time, the X length, and a corresponding Y length (defining an area in a top down or plan view) may be in a range of a first length (e.g., X) in a range of 10 millimeters to 500 millimeters, and a second length (e.g., Y) in a range of 10 millimeters to 500 millimeters, the first length perpendicular to the second length;

In embodiment of substrate 700, 870, and 970, a cavity 701 is formed in the upper surface 703 of the substrate. As may be appreciated, the cavity portion of the substrate comprises a smaller width, area, or volume, of an overall substrate under discussion. The figures reflect cross-sectional views, in which the portion for the dielectric cavity is depicted as a width; however, in a top-down view, the portion for the dielectric cavity would appear as an area. The dielectric cavity is created in the substrate by removing dielectric material to a predetermined depth. A laser drill or ablation process may be used to remove the dielectric material and create the dielectric cavity. Cavity walls are substantially straight (i.e., 90 degrees from perpendicular to an upper surface of the layer of glass 702, plus or minus 20 degrees; however, in other embodiments, the cavity walls may be 90 degrees plus or minus 10 degrees) and may have an internal taper reflecting the drill or ablation process used to open the cavity. Further manufacturing may include laser drilling on the lower surface 705/805/905/1005, via/solder bump plating then SR lamination, SRO opening and solder ball attach.

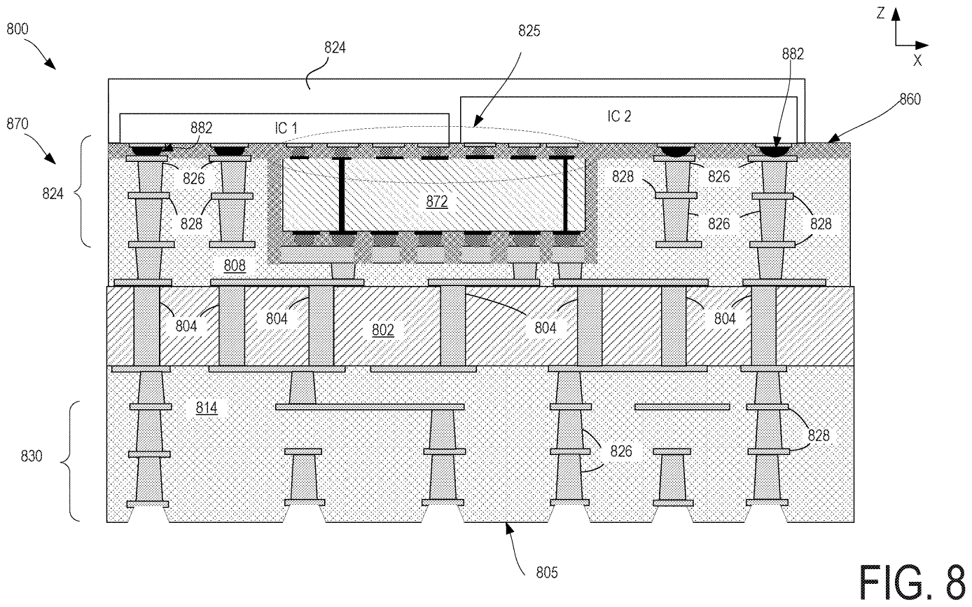

FIG. 8 is a semiconductor package 800 with a multi-die bridge component attached thereto. The reader will recognize IC 1, IC 2, and the encapsulant 824/924, as well as the means for attachment 825/925. The IC 1 and IC 2 are solder attached to the upper surface of the substrate 870/970 with solder bumps 882/982. The multi-die bridge component includes a bridge component 872/972 with TSVs or TGVs and is solder attached to the floor of the cavity, as illustrated. An underfill material 860/960 extends all the way across the upper surface of the substrate 870, following into the cavity around the bridge component 872/972. To identify this embodiment in a SEM or TEM image, one would look for this underflow and confirm that it comprises the same material throughout. Lower surface 805 may have openings created in it for solder bumps.

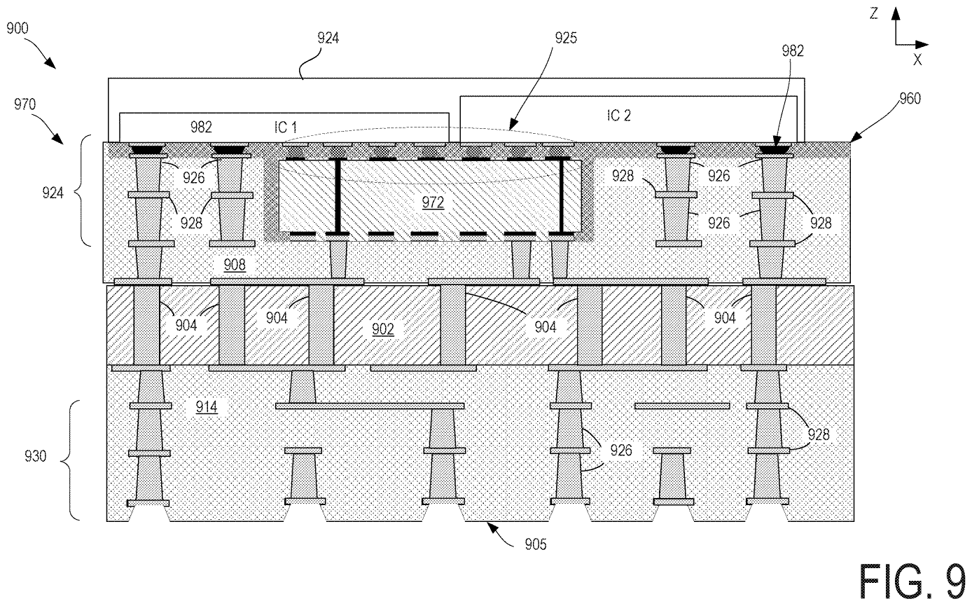

FIG. 9 depicts most of the same objects and components as FIG. 8. In embodiment 900, the multi-die bridge assembly is attached to the substrate 970 using hybrid bonding in the cavity (for the bridge) and solder bonding external to the cavity (for die 1 and die 2 to the substrate). In other embodiments the multi-die bridge component can include a passive bridge component that is attached to the cavity floor with an adhesive material. Lower surface 905 may have openings created in it for solder bumps.

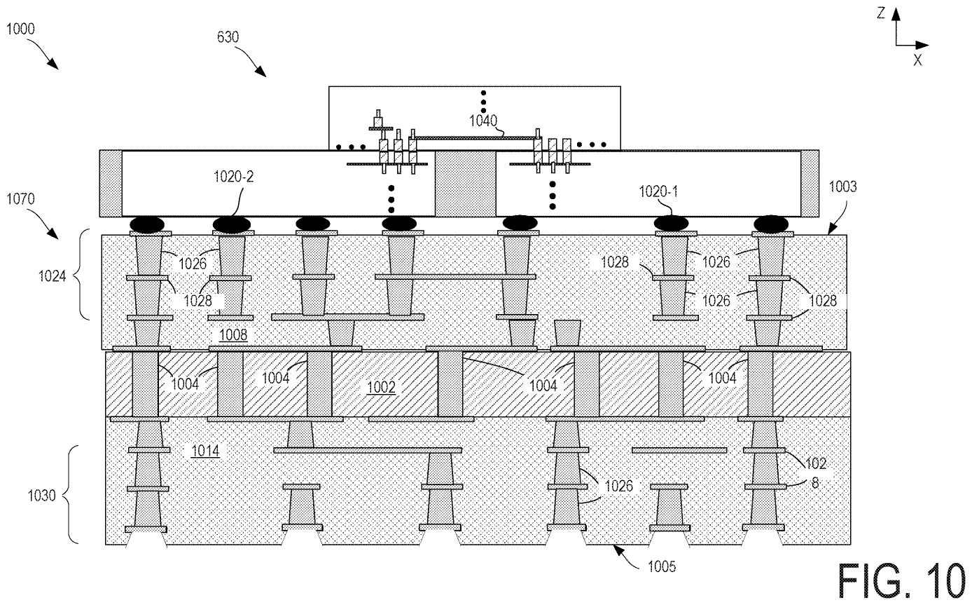

FIG. 10 embodiment 1000 depicts the inverted embodiment of multi-die bridge assembly 630, solder attached to the upper surface 1003 of the substrate 1070 (see, solder attach 1020-1 and solder attach 1020-2). An underfill (not shown) may be added prior to further manufacturing steps. Lower surface 1005 may have openings created in it for solder bumps.

The above embodiments may provide, in a multi-die package assembly, the functionality conventionally associated with a monolithic system on chip (SoC). Further, overmolding and thermal solutions (not shown) may be added.

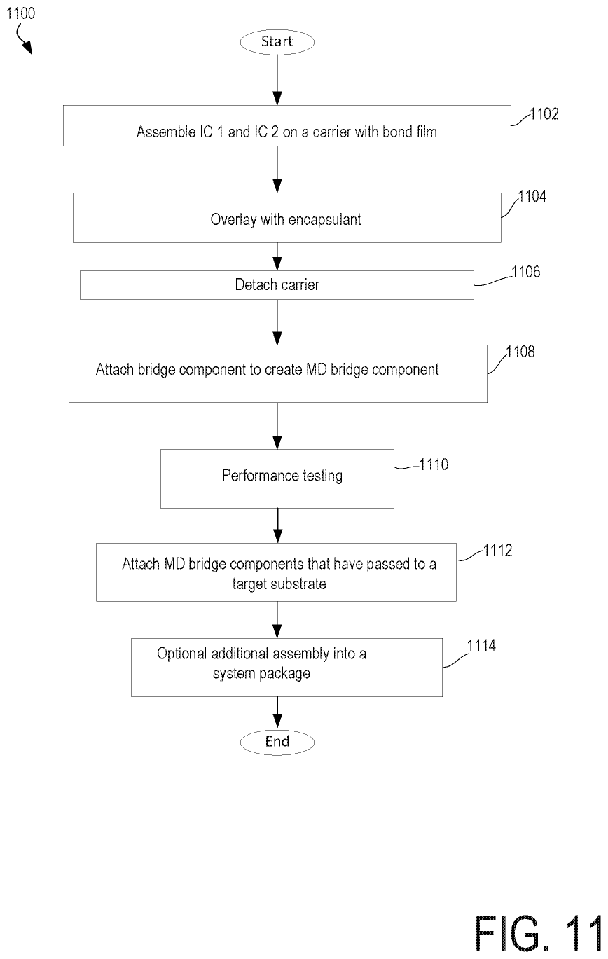

FIG. 11 illustrates a method for a multi-die bridge assembly for 3D semiconductor packaging. The method 1100 includes (at 1102) assembling a first integrated circuit (IC) die and a second IC die on a carrier with an adhesive or bond film. At 1104, a layer of encapsulant or mold compound is overlaid on the first IC and second IC. In some embodiments, a layer of dielectric material is sandwiched between the first IC, the second IC, and the layer of encapsulant.

At 1106, the carrier is detached from the assembly. At 1108, a bridge component is attached to a first portion of the first IC and a first portion of the second IC, to thereby create a multi-die bridge assembly. At 1110, the multi-die bridge assembly is subjected to testing to determine whether it passes performance metrics.

At 1112, a substrate is attached to the multi-die bridge assembly after the multi-die bridge assembly passes the performance metrics. At 1112, wherein the substrate has a cavity, the multi-die bridge assembly is attached to the substrate such that the bridge component is placed in the cavity. As detailed above, there are various ways to attach the bridge component into the cavity, e.g., hybrid bonding, solder bump bonding, adhesive or bond film, thermal compression bonding, or the like. In some embodiments, the substrate does not have a cavity, and the multi-die bridge assembly is attached to the substrate as described in connection with FIG. 10. Upon completion of 1112, the component is referred to as a package assembly.

At 1114, optional additional assembly can be performed to create a system package. The system package may comprise one or more package assemblies from 1112, and/or other integrated circuit components and/or active or passive electronic components.

Thus, various non-limiting embodiments of multi-die assemblies and methods for 3D packaging have been described. Embodiments exhibit distinct features in SEM images, not limited to consistent underfill across MD bridge component and between bridge component and substrate, and/or combined HB and solder attach. The following description provides additional detail and context for various die and various package assembly and device configurations that can be created based on or using the provided embodiments.

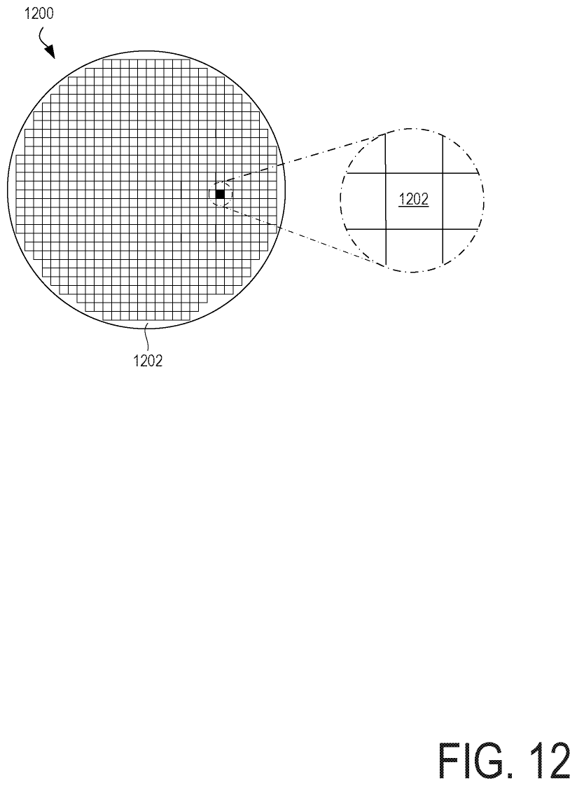

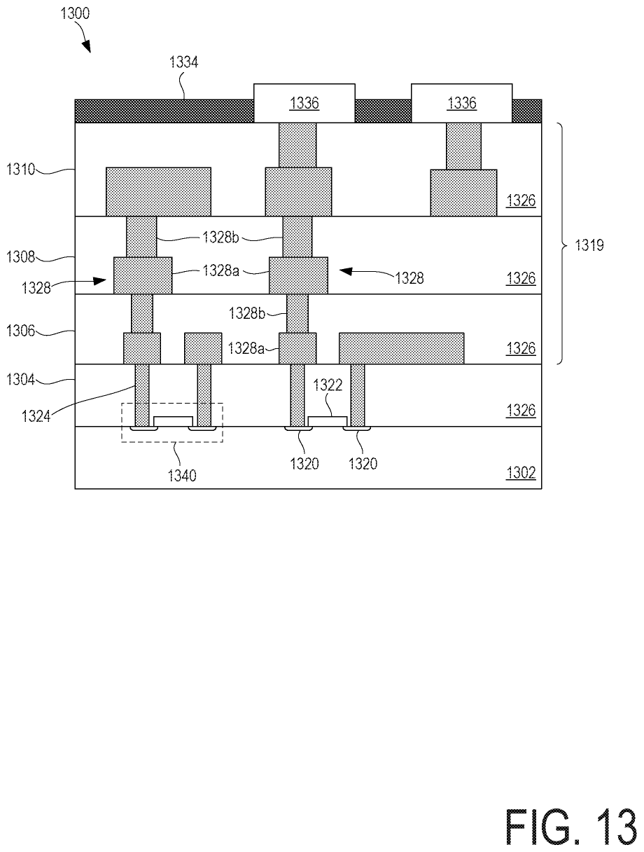

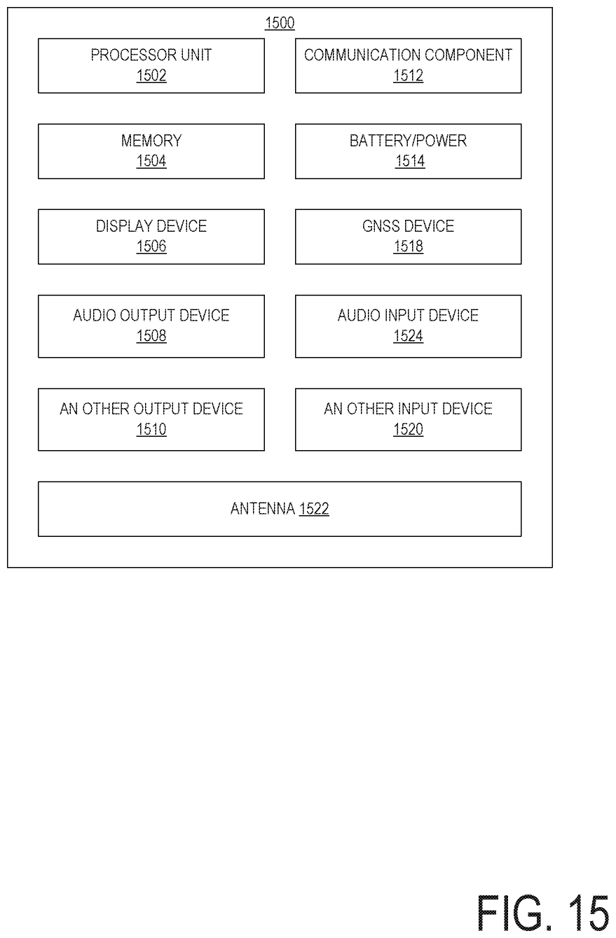

FIG. 12 is a top view of a wafer 1200 and dies 1202 that may be included in any of the embodiments disclosed herein. The wafer 1200 may be composed of semiconductor material and may include one or more dies 1202 formed on a surface of the wafer 1200. After the fabrication of the integrated circuit components on the wafer 1200 is complete, the wafer 1200 may undergo a singulation process in which the dies 1202 are separated from one another to provide discrete “chips” or destined for a packaged integrated circuit component. The individual dies 1202, comprising an integrated circuit component, may include one or more transistors (e.g., some of the transistors 1340 of FIG. 13, discussed below), supporting circuitry to route electrical signals to the transistors, passive components (e.g., signal traces, resistors, capacitors, or inductors), and/or any other integrated circuit components. In some embodiments, the wafer 1200 or the die 1202 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Additionally, multiple devices may be combined on a single die 1202. For example, a memory array formed by multiple memory devices may be formed on a same die 1202 as a processor unit (e.g., the processor unit 1502 of FIG. 15) or other logic that is configured to store information in the memory devices or execute instructions stored in the memory array. In some embodiments, a die 1202 may be attached to a wafer 1200 that includes other die, and the wafer 1200 is subsequently singulated, this manufacturing procedure is referred to as a die-to-wafer assembly technique.

FIG. 13 is a cross-sectional side view of an integrated circuit 1300 that may be included in any of the embodiments disclosed herein. One or more of the integrated circuits 1300 may be included in one or more dies 1202 (FIG. 12). The integrated circuit 1300 may be formed on a die substrate 1302 (e.g., the wafer 1200 of FIG. 12) and may be included in a die (e.g., the die 1202 of FIG. 12).

The die substrate 1302 may be a semiconductor substrate composed of semiconductor material systems including, for example, n-type or p-type materials systems (or a combination of both). The die substrate 1302 may include, for example, a crystalline substrate formed using a bulk silicon or a silicon-on-insulator (SOI) substructure. In some embodiments, the die substrate 1302 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1302. Although a few examples of materials from which the die substrate 1302 may be formed are described here, any material that may serve as a foundation for an integrated circuit 1300 may be used. The die substrate 1302 may be part of a singulated die (e.g., the dies 1202 of FIG. 12) or a wafer (e.g., the wafer 1200 of FIG. 12).

The integrated circuit 1300 may include one or more device layers 1304 disposed on the die substrate 1302. The device layer 1304 may include features of one or more transistors 1340 (e.g., metal oxide semiconductor field-effect transistors (MOSFETs)) formed on the die substrate 1302. The transistors 1340 may include, for example, one or more source and/or drain (S/D) regions 1320, a gate 1322 to control current flow between the S/D regions 1320, and one or more S/D contacts 1324 to route electrical signals to/from the S/D regions 1320.

The gate 1322 may be formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be conducted on the gate dielectric to improve its quality when a high-k material is used.

The gate electrode may be formed on the gate dielectric and may include at least one p-type work function metal or n-type work function metal, depending on whether the transistor 1340 is to be a p-type metal oxide semiconductor (PMOS) or an n-type metal oxide semiconductor (NMOS) transistor. In some implementations, the gate electrode may comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1340 along the source-channel-drain direction, the gate electrode may comprise a U-shaped structure that includes a bottom portion substantially parallel to the surface of the die substrate 1302 and two sidewall portions that are substantially perpendicular to the top surface of the die substrate 1302. In other embodiments, at least one of the metal layers that form the gate electrode may simply be a planar layer that is substantially parallel to the top surface of the die substrate 1302 and does not include sidewall portions substantially perpendicular to the top surface of the die substrate 1302. In other embodiments, the gate electrode may comprise a combination of U-shaped structures and planar, non-U-shaped structures. For example, the gate electrode may comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and include deposition and etching processes. In some embodiments, a plurality of spacer pairs may be used; for instance, two pairs, three pairs, or four pairs of sidewall spacers may be formed on opposing sides of the gate stack.

The S/D regions 1320 may be formed within the die substrate 1302 adjacent to the gate 1322 of individual transistors 1340. The S/D regions 1320 may be formed using an implantation/diffusion process or an etching/deposition process, for example. In the former process, dopants such as boron, aluminum, antimony, phosphorous, or arsenic may be ion-implanted into the die substrate 1302 to form the S/D regions 1320. An annealing process that activates the dopants and causes them to diffuse farther into the die substrate 1302 may follow the ion-implantation process. In the latter process, the die substrate 1302 may first be etched to form recesses at the locations of the S/D regions 1320. An epitaxial deposition process may then be conducted to fill the recesses with material that is used to fabricate the S/D regions 1320. In some implementations, the S/D regions 1320 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1320 may be formed using one or more alternate semiconductor materials such as germanium or a group III-V material or alloy. In further embodiments, one or more layers of metal and/or metal alloys may be used to form the S/D regions 1320.

Electrical signals, such as power and/or input/output (I/O) signals, may be routed to and/or from the devices (e.g., transistors 1340) of the device layer 1304 through one or more interconnect layers disposed on the device layer 1304 (illustrated in FIG. 13 as interconnect layers 1306-1310). For example, electrically conductive features of the device layer 1304 (e.g., the gate 1322 and the S/D contacts 1324) may be electrically coupled with the interconnect structures 1328 of the interconnect layers 1306-1310. The one or more interconnect layers 1306-1310 may form a metallization stack (also referred to as an “ILD stack”) 1319 of the integrated circuit 1300.

The interconnect structures 1328 may be arranged within the interconnect layers 1306-1310 to route electrical signals according to a wide variety of designs; in particular, the arrangement is not limited to the particular configuration of interconnect structures 1328 depicted in FIG. 13. Although a particular number of interconnect layers 1306-1310 is depicted in FIG. 13, embodiments of the present disclosure include integrated circuits having more or fewer interconnect layers than depicted.

In some embodiments, the interconnect structures 1328 may include lines 1328a and/or vias 1328b filled with an electrically conductive material such as a metal. The lines 1328a may be arranged to route electrical signals in a direction of a plane that is substantially parallel with a surface of the die substrate 1302 upon which the device layer 1304 is formed. For example, the lines 1328a may route electrical signals in a direction in and out of the page and/or in a direction across the page. The vias 1328b may be arranged to route electrical signals in a direction of a plane that is substantially perpendicular to the surface of the die substrate 1302 upon which the device layer 1304 is formed. In some embodiments, the vias 1328b may electrically couple lines 1328a of different interconnect layers 1306-1310 together.

The interconnect layers 1306-1310 may include a dielectric material 1326 disposed between the interconnect structures 1328, as shown in FIG. 13. In some embodiments, dielectric material 1326 disposed between the interconnect structures 1328 in different ones of the interconnect layers 1306-1310 may have different compositions; in other embodiments, the composition of the dielectric material 1326 between different interconnect layers 1306-1310 may be the same. The device layer 1304 may include a dielectric material 1326 disposed between the transistors 1340 and a bottom layer of the metallization stack as well. The dielectric material 1326 included in the device layer 1304 may have a different composition than the dielectric material 1326 included in the interconnect layers 1306-1310; in other embodiments, the composition of the dielectric material 1326 in the device layer 1304 may be the same as a dielectric material 1326 included in any one of the interconnect layers 1306-1310.

A first interconnect layer 1306 (referred to as Metal 1 or “M1”) may be formed directly on the device layer 1304. In some embodiments, the first interconnect layer 1306 may include lines 1328a and/or vias 1328b, as shown. The lines 1328a of the first interconnect layer 1306 may be coupled with contacts (e.g., the S/D contacts 1324) of the device layer 1304. The vias 1328b of the first interconnect layer 1306 may be coupled with the lines 1328a of a second interconnect layer 1308.

The second interconnect layer 1308 (referred to as Metal 2 or “M2”) may be formed directly on the first interconnect layer 1306. In some embodiments, the second interconnect layer 1308 may include via 1328b to couple the lines of interconnect structures 1328 of the second interconnect layer 1308 with the lines 1328a of a third interconnect layer 1310. Although the lines 1328a and the vias 1328b are structurally delineated with a line within individual interconnect layers for the sake of clarity, the lines 1328a and the vias 1328b may be structurally and/or materially contiguous (e.g., simultaneously filled during a dual-damascene process) in some embodiments.

The third interconnect layer 1310 (referred to as Metal 3 or “M3”) (and additional interconnect layers, as desired) may be formed in succession on the second interconnect layer 1308 according to similar techniques and configurations described in connection with the second interconnect layer 1308 or the first interconnect layer 1306. In some embodiments, the interconnect layers that are “higher up” in the metallization stack 1319 in the integrated circuit 1300 (i.e., farther away from the device layer 1304) may be thicker that the interconnect layers that are lower in the metallization stack 1319, with lines 1328a and vias 1328b in the higher interconnect layers being thicker than those in the lower interconnect layers.

The integrated circuit 1300 may include a solder resist material 1334 (e.g., polyimide or similar material) and one or more conductive contacts 1336 formed on the interconnect layers 1306-1310. In FIG. 13, the conductive contacts 1336 are illustrated as taking the form of bond pads. The conductive contacts 1336 may be electrically coupled with the interconnect structures 1328 and configured to route the electrical signals of the transistor(s) 1340 to external devices. For example, solder bonds may be formed on the one or more conductive contacts 1336 to mechanically and/or electrically couple an integrated circuit die including the integrated circuit 1300 with another component (e.g., a printed circuit board). The integrated circuit 1300 may include additional or alternate structures to route the electrical signals from the interconnect layers 1306-1310; for example, the conductive contacts 1336 may include other analogous features (e.g., posts) that route the electrical signals to external components.

In some embodiments in which the integrated circuit 1300 is a double-sided die, the integrated circuit 1300 may include another metallization stack (not shown) on the opposite side of the device layer(s) 1304. This metallization stack may include multiple interconnect layers as discussed above with reference to the interconnect layers 1306-1310, to provide electrically conductive paths (e.g., including conductive lines and vias) between the device layer(s) 1304 and additional conductive contacts (not shown) on the opposite side of the integrated circuit 1300 from the conductive contacts 1336.

In other embodiments in which the integrated circuit 1300 is a double-sided die, the integrated circuit 1300 may include one or more through-silicon vias (TSVs) through the die substrate 1302; these TSVs may make contact with the device layer(s) 1304, and may provide electrically conductive paths between the device layer(s) 1304 and additional conductive contacts (not shown) on the opposite side of the integrated circuit 1300 from the conductive contacts 1336. In some embodiments, TSVs extending through the substrate can be used for routing power and ground signals from conductive contacts on the opposite side of the integrated circuit 1300 from the conductive contacts 1336 to the transistors 1340 and any other components integrated into the integrated circuit 1300 die, and the metallization stack 1319 can be used to route I/O signals from the conductive contacts 1336 to transistors 1340 and any other components integrated into the integrated circuit 1300 die.

Multiple integrated circuits 1300 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

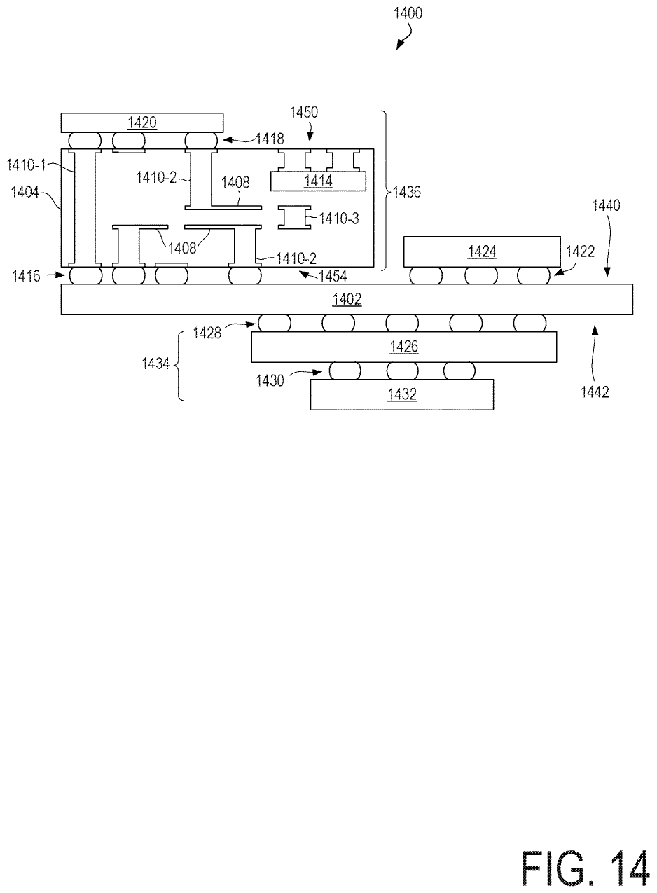

FIG. 14 is a cross-sectional side view of a microelectronic assembly 1400 that may include any of the embodiments disclosed herein. The microelectronic assembly 1400 includes multiple integrated circuit components disposed on a circuit board 1402 (which may be a motherboard, system board, mainboard, etc.). The microelectronic assembly 1400 may include components disposed on a first face 1440 of the circuit board 1402 and an opposing second face 1442 of the circuit board 1402; generally, components may be disposed on one or both faces 1440 and 1442.

In some embodiments, the circuit board 1402 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1402. In other embodiments, the circuit board 1402 may be a non-PCB substrate. The microelectronic assembly 1400 illustrated in FIG. 14 includes a package-on-interposer structure 1436 coupled to the first face 1440 of the circuit board 1402 by coupling components 1416. The coupling components 1416 may electrically and mechanically couple the package-on-interposer structure 1436 to the circuit board 1402, and may include solder balls (as shown in FIG. 14), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1436 may include an integrated circuit component 1420 coupled to an interposer 1404 by coupling components 1418. The coupling components 1418 may take any suitable form for the application, such as the forms discussed above with reference to the coupling components 1416. Although a single integrated circuit component 1420 is shown in FIG. 14, multiple integrated circuit components may be coupled to the interposer 1404; indeed, additional interposers may be coupled to the interposer 1404. The interposer 1404 may provide an intervening substrate used to bridge the circuit board 1402 and the integrated circuit component 1420.

The integrated circuit component 1420 may be a packaged or unpackaged integrated circuit component that includes one or more integrated circuit dies (e.g., the die 1202 of FIG. 12, the integrated circuit 1300 of FIG. 13) and/or one or more other suitable components.

The unpackaged integrated circuit component 1420 comprises solder bumps attached to contacts on the die. The solder bumps allow the die to be directly attached to the interposer 1404. In embodiments where the integrated circuit component 1420 comprises multiple integrated circuit die, the dies can be of the same type (a homogeneous multi-die integrated circuit component) or of two or more different types (a heterogeneous multi-die integrated circuit component). In addition to comprising one or more processor units, the integrated circuit component 1420 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate, or combinations thereof. A packaged multi-die integrated circuit component can be referred to as a multi-chip package (MCP) or multi-chip module (MCM).

The interposer 1404 may spread connections to a wider pitch or reroute a connection to a different connection. For example, the interposer 1404 may couple the integrated circuit component 1420 to a set of ball grid array (BGA) conductive contacts of the coupling components 1416 for coupling to the circuit board 1402. In the embodiment illustrated in FIG. 14, the integrated circuit component 1420 and the circuit board 1402 are attached to opposing sides of the interposer 1404; in other embodiments, the integrated circuit component 1420 and the circuit board 1402 may be attached to a same side of the interposer 1404. In some embodiments, three or more components may be interconnected by way of the interposer 1404.

In some embodiments, the interposer 1404 may be formed as a PCB, including multiple metal layers separated from one another by layers of dielectric material and interconnected by electrically conductive vias. In some embodiments, the interposer 1404 may be formed of an epoxy resin, a fiberglass-reinforced epoxy resin, an epoxy resin with inorganic fillers, a ceramic material, or a polymer material such as polyimide. In some embodiments, the interposer 1404 may be formed of alternate rigid or flexible materials that may include the same materials described above for use in a semiconductor substrate, such as silicon, germanium, and other group III-V and group IV materials. The interposer 1404 may include metal interconnects 1408 and vias 1410, including but not limited to through hole vias 1410-1 (that extend from a first face 1450 of the interposer 1404 to a second face 1454 of the interposer 1404), blind vias 1410-2 (that extend from the first or second faces 1450 or 1454 of the interposer 1404 to an internal metal layer), and buried vias 1410-3 (that connect internal metal layers).

In some embodiments, the interposer 1404 can comprise a silicon interposer. Through-silicon vias (TSV) extending through the silicon interposer can connect connections on a first face of a silicon interposer to an opposing second face of the silicon interposer. In some embodiments, an interposer 1404 comprising a silicon interposer can further comprise one or more routing layers to route connections on a first face of the interposer 1404 to an opposing second face of the interposer 1404.

The interposer 1404 may further include embedded devices 1414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1404. The package-on-interposer structure 1436 may take the form of any of the package-on-interposer structures known in the art.

The integrated circuit assembly 1400 may include an integrated circuit component 1424 coupled to the first face 1440 of the circuit board 1402 by coupling components 1422. The coupling components 1422 may take the form of any of the embodiments discussed above with reference to the coupling components 1416, and the integrated circuit component 1424 may take the form of any of the embodiments discussed above with reference to the integrated circuit component 1420.

The integrated circuit assembly 1400 illustrated in FIG. 14 includes a package-on-package structure 1434 coupled to the second face 1442 of the circuit board 1402 by coupling components 1428. The package-on-package structure 1434 may include an integrated circuit component 1426 and an integrated circuit component 1432 coupled together by coupling components 1430 such that the integrated circuit component 1426 is disposed between the circuit board 1402 and the integrated circuit component 1432. The coupling components 1428 and 1430 may take the form of any of the embodiments of the coupling components 1416 discussed above, and the integrated circuit components 1426 and 1432 may take the form of any of the embodiments of the integrated circuit component 1420 discussed above. The package-on-package structure 1434 may be configured in accordance with any of the package-on-package structures known in the art.

FIG. 15 is a block diagram of an example electrical device 1500 that may include one or more of the embodiments disclosed herein. For example, any suitable ones of the components of the electrical device 1500 may include one or more of the microelectronic assemblies 1400, integrated circuit components 1420, integrated circuits 1300, integrated circuit dies 1202, or structures disclosed herein. A number of components are illustrated in FIG. 15 as included in the electrical device 1500, but any one or more of these components may be omitted or duplicated, as suitable for the application. In some embodiments, some or all the components included in the electrical device 1500 may be attached to one or more motherboards, mainboards, printed circuit boards, or system boards. In some embodiments, one or more of these components are fabricated onto a single system-on-a-chip (SoC) die. In various embodiments, the electrical device 3000 is enclosed by, or integrated with, a housing.

Additionally, in various embodiments, the electrical device 1500 may not include one or more of the components illustrated in FIG. 15, but the electrical device 1500 may include interface circuitry for coupling to the one or more components. For example, the electrical device 1500 may not include a display device 1506, but may include display device interface circuitry (e.g., a connector and driver circuitry) to which a display device 1506 may be coupled. In another set of examples, the electrical device 1500 may not include an audio input device 1524 or an audio output device 1508, but may include audio input or output device interface circuitry (e.g., connectors and supporting circuitry) to which an audio input device 1524 or audio output device 1508 may be coupled.

The electrical device 1500 may include one or more processor units 1502 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1502 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller crypto processors (specialized processors that execute cryptographic algorithms within hardware), server processors, controllers, or any other suitable type of processor units. As such, the processor unit can be referred to as an XPU (or xPU).

The electrical device 1500 may include a memory 1504, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1504 may include memory that is located on the same integrated circuit die as the processor unit 1502. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments, the electrical device 1500 can comprise one or more processor units 1502 that are heterogeneous or asymmetric to another processor unit 1502 in the electrical device 1500. There can be a variety of differences between the processor units 1502 in a system in terms of a spectrum of metrics of merit including architectural, microarchitectural, thermal, power consumption characteristics, and the like. These differences can effectively manifest themselves as asymmetry and heterogeneity among the processor units 1502 in the electrical device 1500.

In some embodiments, the electrical device 1500 may include a communication component 1512 (e.g., one or more communication components). For example, the communication component 1512 can manage wireless communications for the transfer of data to and from the electrical device 1500. The term “wireless” and its derivatives may be used to describe circuits, devices, systems, methods, techniques, communications channels, etc., that may communicate data using modulated electromagnetic radiation through a nonsolid medium. The term “wireless” does not imply that the associated devices do not contain any wires, although in some embodiments they might not.

The communication component 1512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1512 may operate in accordance with other wireless protocols in other embodiments. The electrical device 1500 may include an antenna 1522 to facilitate wireless communications and/or to receive other wireless communications (such as AM or FM radio transmissions).

In some embodiments, the communication component 1512 may manage wired communications, such as electrical, optical, or any other suitable communication protocols (e.g., IEEE 802.3 Ethernet standards). As noted above, the communication component 1512 may include multiple communication components. For instance, a first communication component 1512 may be dedicated to shorter-range wireless communications such as Wi-Fi or Bluetooth, and a second communication component 1512 may be dedicated to longer-range wireless communications such as global positioning system (GPS), EDGE, GPRS, CDMA, WiMAX, LTE, EV-DO, or others. In some embodiments, a first communication component 1512 may be dedicated to wireless communications, and a second communication component 1512 may be dedicated to wired communications.

The electrical device 1500 may include battery/power circuitry 1514. The battery/power circuitry 1514 may include one or more energy storage devices (e.g., batteries or capacitors) and/or circuitry for coupling components of the electrical device 1500 to an energy source separate from the electrical device 1500 (e.g., AC line power).

The electrical device 1500 may include a display device 1506 (or corresponding interface circuitry, as discussed above). The display device 1506 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1500 may include an audio output device 1508 (or corresponding interface circuitry, as discussed above). The audio output device 1508 may include any embedded or wired or wirelessly connected external device that generates an audible indicator, such speakers, headsets, or earbuds.

The electrical device 1500 may include an audio input device 1524 (or corresponding interface circuitry, as discussed above). The audio input device 1524 may include any embedded or wired or wirelessly connected device that generates a signal representative of a sound, such as microphones, microphone arrays, or digital instruments (e.g., instruments having a musical instrument digital interface (MIDI) output). The electrical device 1500 may include a Global Navigation Satellite System (GNSS) device 1518 (or corresponding interface circuitry, as discussed above), such as a Global Positioning System (GPS) device. The GNSS device 1518 may be in communication with a satellite-based system and may determine a geolocation of the electrical device 1500 based on information received from one or more GNSS satellites, as known in the art.

The electrical device 1500 may include another output device 1510 (or corresponding interface circuitry, as discussed above). Examples of the other output device 1510 may include an audio codec, a video codec, a printer, a wired or wireless transmitter for providing information to other devices, or an additional storage device.

The electrical device 1500 may include another input device 1520 (or corresponding interface circuitry, as discussed above). Examples of the other input device 1520 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1500 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1500 may be any other electronic device that processes data. In some embodiments, the electrical device 1500 may comprise multiple discrete physical components. Given the range of devices that the electrical device 1500 can be manifested as in various embodiments, in some embodiments, the electrical device 1500 can be referred to as a computing device or a computing system.

While at least one embodiment has been presented in the foregoing detailed description, it should be appreciated that a vast number of variations exist. It should also be appreciated that the disclosed embodiments are only examples, and are not intended to limit the scope, applicability, or configuration of the disclosure in any way. Rather, the foregoing detailed description will provide those skilled in the art with a convenient road map for implementing the disclosed embodiment embodiments. Various changes can be made in the function and arrangement of elements without departing from the scope of the disclosure as set forth in the appended claims and the legal equivalents thereof.

As used herein, the term “electronic component” can refer to an active electronic circuit (e.g., processing unit, memory, storage device, FET) or a passive electronic circuit (e.g., resistor, inductor, capacitor).

As used herein, the term and “integrated circuit component” can refer to an electronic component configured on a semiconducting material to perform a function. An integrated circuit (IC) component can comprise one or more of any computing system components described or referenced herein or any other computing system component, such as a processor unit (e.g., system-on-a-chip (SoC), processor core, graphics processor unit (GPU), accelerator, chipset processor), I/O controller, memory, or network interface controller, and can comprise one or more additional active or passive devices such as capacitors, decoupling capacitors, resistors, inductors, fuses, diodes, transformers, sensors, electrostatic discharge (ESD) devices, and memory devices.

A non-limiting example of an unpackaged integrated circuit component includes a single monolithic integrated circuit die; the die may include solder bumps attached to contacts on the die. When present on the die, the solder bumps or other conductive contacts can enable the die to be directly attached to a printed circuit board (PCB) or other substrates.

A non-limiting example of a packaged integrated circuit component comprises one or more integrated circuit dies mounted on a package substrate with the integrated circuit dies and package substrate encapsulated in a casing material, such as a metal, plastic, glass, or ceramic. Often the casing includes an integrated heat spreader (IHS); the packaged integrated circuit component often has bumps, leads, or pins attached to the package substrate (either directly or by wires attaching the bumps, leads, or pins to the package substrate) for attaching the packaged integrated circuit component to a printed circuit board (or motherboard or base board) or another component.

As used herein, phrases such as “an embodiment,” “various embodiments,” “some embodiments,” and the like, indicate that some embodiments may have some, all, or none of the features described for other embodiments. “First,” “second,” “third,” and the like describe a common object and indicate different instances of like objects being referred to; unless specifically stated, they do not imply a given sequence, either temporally or spatially, in ranking, or any other manner. In accordance with patent application parlance, “connected” indicates elements that are in direct physical or electrical contact with each other and “coupled” indicates elements that co-operate or interact with each other, coupled elements may or may not be in direct physical or electrical contact. Furthermore, the terms “comprising,” “including,” “having,” and the like, are utilized synonymously to denote non-exclusive inclusions.

As used in this application and the claims, a list of items joined by the term “at least one of” or the term “one or more of” can mean any combination of the listed terms. For example, the phrase “at least one of A, B or C” can mean A; B; C; A and B; A and C; B and C; or A, B, and C. Likewise, the phrase “one or more of A, B and C” can mean A; B; C; A and B; A and C; B and C; or A, B, and C.

As used in this application and the claims, the phrase “individual of” or “respective of” following by a list of items recited or stated as having a trait, feature, etc. means that all the items in the list possess the stated or recited trait, feature, etc. For example, the phrase “individual of A, B, or C, comprise a sidewall” or “respective of A, B, or C, comprise a sidewall” means that A comprises a sidewall, B comprises sidewall, and C comprises a sidewall.

Theories of operation, scientific principles, or other theoretical descriptions presented herein in reference to the apparatuses or methods of this disclosure have been provided for the purposes of better understanding and are not intended to be limiting in scope. The apparatuses and methods in the appended claims are not limited to those apparatuses and methods that function in the manner described by such theories of operation.

The following examples pertain to additional embodiments of technologies disclosed herein.

### EXAMPLES

Example 1 is a semiconductor assembly, comprising: a bridge component comprising a first insulating material and defined by a first surface and a second surface, the first surface comprising a plurality of first metal contacts therein, the plurality of first metal contacts organized into a first area and a second area; wherein the bridge component provides at least one electrical pathway between a first first metal contact in the first area and a second first metal contact in the second area; a first die comprising a first upper surface with a second insulating material and a plurality of second metal contacts therein; wherein the first upper surface is on the first area of the first surface, wherein the first insulating material is directly bonded to the second insulating material and some first metal contacts are directly bonded to a respective second metal contact; a second die comprising a second upper surface with a third insulating material and a plurality of third metal contacts therein; wherein the second upper surface is on the second area of the first surface, wherein the first insulating material is directly bonded to the third insulating material and other first metal contacts are directly bonded to a respective third metal contact.

Example 2 includes the subject matter of Example 1, further comprising at least one contact on the second surface that provides an electrical pathway to the first surface.

Example 3 includes the subject matter of Example 1, wherein the first die comprises a processing or graphics integrated circuit and the second die comprises a memory device.

Example 4 includes the subject matter of Example 1, wherein the first insulating material, the second insulating material, and the third insulating material are dielectric materials.

Example 5 includes the subject matter of Example 1, wherein the plurality of first metal contacts, the plurality of second metal contacts and the plurality of third metal contacts comprise copper.

Example 6 includes the subject matter of Example 1, wherein the plurality of first metal contacts, the plurality of second metal contacts and the plurality of third metal contacts are hybrid bond conductive contacts.

Example 7 includes the subject matter of Example 2, further comprising one or more solder bumps attached to the second surface.

Example 8 includes the subject matter of Example 1 or claim 2, wherein the first die further has a first lower surface, and the second die further has a second lower surface, and further comprising: a mold compound overlaid on the first lower surface and the second lower surface.

Example 9 includes the subject matter of Example 8, further comprising a layer of dielectric material between the mold compound and the first lower surface and between the mold compound and the second lower surface.

Example 10 includes the subject matter of Example 8, further comprising underfill between the first surface and the first upper surface, and the underfill between the first surface and the second upper surface.

Example 11 includes the subject matter of Example 8, further comprising a glass structure between the first die and the second die, the glass structure in contact with the first surface of the bridge component.

Example 12 is a semiconductor package comprising the subject matter of Example 1, and further comprising: a substrate comprising one or more dielectric layers, individual dielectric layers including a respective redistribution layer (RDL); wherein the substrate includes a cavity formed on a top surface; the semiconductor assembly attached to the substrate with the bridge component in the cavity, and the first upper surface and the second upper surface extend across the top surface.

Example 13 is a semiconductor package comprising the subject matter of Example 2, and further comprising: a substrate comprising one or more dielectric layers, individual dielectric layers including a respective redistribution layers (RDLs); wherein the substrate includes a cavity formed on a top surface; a layer of solder material in the cavity; the semiconductor assembly attached to the substrate with the bridge component attached via solder bumps to the layer of solder material in the cavity, and the first upper surface and the second upper surface extend across the top surface.

Example 14 includes the subject matter of Example 13, further comprising an underfill material located between the first upper surface and the first surface, the cavity and the bridge component, and the second upper surface and the first surface.

Example 15 is a semiconductor package comprising the subject matter of Example 2, and further comprising: a substrate comprising one or more dielectric layers, individual dielectric layers including a respective redistribution layers (RDLs); wherein the substrate includes a cavity formed on a top surface, the cavity comprising dielectric material with metal pads therein; the semiconductor assembly attached to the substrate with the bridge component attached in the cavity via direct bonding of the at least one contact to a respective metal pad and the dielectric material directly bonded to the first insulating material in the second surface, wherein the first upper surface and the second upper surface extend across the top surface.

Example 16 is a semiconductor package comprising the subject matter of Example 1, and further comprising: a substrate comprising one or more dielectric layers, individual dielectric layers including a respective redistribution layers (RDLs); the first die comprising a first lower surface; the second die comprising a second lower surface; the semiconductor assembly on the substrate with the first lower surface and the second lower surface attached to a top surface of the substrate via solder bumps.

Example 17 is the semiconductor package of any one of Examples 12-16, wherein: the substrate includes a layer of glass having a thickness in a range of 20 microns to 1.4 millimeters, a first length in a range of 10 millimeters to 500 millimeters, and a second length in a range of 10 millimeters to 500 millimeters, the first length perpendicular to the second length; and the layer of glass comprises multiple through-glass vias.

Example 18 is a package assembly, comprising: a multi-die bridge assembly, including a processing unit die with a first upper surface and a first lower surface, a memory die with a second upper surface and second lower surface, and a bridge component attached on a first surface to a first portion of the first upper surface and a first portion of the second upper surface of the memory die, the bridge component includes a plurality pathways for electrical communication between the processing unit die and the memory die; and a substrate, comprising one or more dielectric layers, individual dielectric layers including a respective redistribution layer (RDL), wherein the substrate includes a cavity formed on a top surface; wherein the multi-die bridge assembly is attached to the substrate such that the bridge component is in the cavity, and a second portion of the first upper surface and a second portion of the second upper surface extend across the top surface.

Example 19 includes the subject matter of Example 18, wherein the bridge component is attached on the first surface to the first portion of the first upper surface and the first portion of the second upper surface of the memory die via hybrid bonding.

Example 20 includes the subject matter of Example 18, wherein the second portion of the first upper surface and the second portion of the second upper surface are hybrid bonded to the top surface.

Example 21 is a method, comprising: assembling a first integrated circuit (IC) die and a second IC die on a carrier with a bond film; locating a layer of mold compound over the first IC and second IC; detaching the carrier; attaching a bridge component to a first portion of the first IC and a first portion of the second IC, to thereby create a multi-die bridge assembly; testing the multi-die bridge assembly to determine whether it passes performance metrics; and attaching a substrate to the multi-die bridge assembly when the multi-die bridge assembly passes the performance metrics to thereby create a package assembly.

Example 22 includes the subject matter of Example 21, wherein the bridge component comprises any combination of one or more of silicon, an organic material, and glass.

Example 23 includes the subject matter of Example 21 or Example 22, wherein the substrate has a cavity and attaching the substrate to the multi-die bridge assembly includes placing the bridge component in the cavity.

Example 24 includes the subject matter of any one of Examples 21-23, wherein attaching the bridge component to the first portion of the first IC and the first portion of the second IC is achieved with hybrid bonding.

Example 25 includes the subject matter of any one of Examples 21-23, wherein attaching the bridge component to the first portion of the first IC and the first portion of the second IC is achieved with solder bumps.

Example 26 includes the subject matter of any one of Examples 21-25, further comprising assembling two or more package assemblies into a system package.

What is claimed is:

1. A multi-die bridge assembly, comprising:
a bridge component having a top side above a bottom side, and sidewalls between the top side and the bottom side, the bridge component having though silicon vias (TSVs) therein;
a first via laterally spaced apart from a sidewall of the bridge component;
a second via beneath the bottom side of the bridge component, wherein one of the TSVs of the bridge component is vertically overlapping with and coupled to the second via;
a third via beneath and coupled to the first via such that the first via is vertically overlapping with the third via, the third via laterally spaced apart from the second via, and the third via having a width greater than a width of the second via;
a first trace beneath and coupled to the second via, and a second trace beneath and coupled to the third via, the second trace laterally spaced apart from the first trace;
a fourth via beneath and coupled to the first trace, wherein the fourth via is not vertically overlapping with the second via;
a fifth via beneath and coupled to the second trace, wherein the fifth via is vertically overlapping with the third via;
a first integrated circuit (IC) die vertically over coupled to the top side of the bridge component and vertically over and coupled to the first via, the first IC die having a first thickness;
a second IC die vertically over and coupled to the top side of the bridge component and laterally spaced apart from the first IC die, the second IC die having a second thickness less than the first thickness; and
an encapsulant over the second IC die.

2. The multi-die bridge assembly of claim 1, wherein the encapsulant is between the second IC die and the first IC die.

3. The multi-die bridge assembly of claim 1, wherein the encapsulant is over the first IC die.

4. The multi-die bridge assembly of claim 1, wherein the encapsulant is along sides of the first IC die.

5. The multi-die bridge assembly of claim 1, wherein first via has a bottom surface at a level above the bottom side of the bridge component.

6. The multi-die bridge assembly of claim 1, further comprising:
a sixth via vertically between the first via and the third via.

7. The multi-die bridge assembly of claim 1, further comprising:
a sixth via laterally between the first via and the bridge component.

8. A multi-die bridge assembly, comprising:
a component having a top side above a bottom side, and sidewalls between the top side and the bottom side, the component having a though silicon via (TSV) therein;
a first conductive structure laterally spaced apart from a sidewall of the component;
a second conductive structure beneath the bottom side of the component, wherein the TSV of the component is vertically overlapping with and coupled to the second conductive structure;
a third conductive structure beneath and coupled to the first conductive structure such that the first conductive structure is vertically overlapping with the third conductive structure, the third conductive structure laterally spaced apart from the second conductive structure, and the third conductive structure having a width greater than a width of the second conductive structure;
a first conductive trace beneath and coupled to the second conductive structure, and a second conductive trace beneath and coupled to the third conductive structure, the second conductive trace laterally spaced apart from the first conductive trace;
a fourth conductive structure beneath and coupled to the first conductive trace, wherein the fourth conductive structure is not vertically overlapping with the second conductive structure;
a fifth conductive structure beneath and coupled to the second conductive trace, wherein the fifth conductive structure is vertically overlapping with the third conductive structure;
a first integrated circuit (IC) die vertically over coupled to the top side of the component and vertically over and coupled to the first conductive structure, the first IC die having a first thickness;
a second IC die vertically over and coupled to the top side of the component and laterally spaced apart from the first IC die, the second IC die having a second thickness less than the first thickness; and
an encapsulant over the second IC die.

9. The multi-die bridge assembly of claim 8, wherein the encapsulant is between the second IC die and the first IC die.

10. The multi-die bridge assembly of claim 8, wherein the encapsulant is over the first IC die.

11. The multi-die bridge assembly of claim 8, wherein the encapsulant is along sides of the first IC die.

12. The multi-die bridge assembly of claim 8, wherein first conductive structure has a bottom surface at a level above the bottom side of the component.

13. The multi-die bridge assembly of claim 8, further comprising:
a sixth conductive structure vertically between the first conductive structure and the third conductive structure.

14. A method of fabricating a multi-die bridge assembly, the method comprising:
providing a bridge component having a top side above a bottom side, and sidewalls between the top side and the bottom side, the bridge component having though silicon vias (TSVs) therein;
forming a first via laterally spaced apart from a sidewall of the bridge component;
forming a second via beneath the bottom side of the bridge component, wherein one of the TSVs of the bridge component is vertically overlapping with and coupled to the second via;
forming a third via beneath and coupled to the first via such that the first via is vertically overlapping with the third via, the third via laterally spaced apart from the second via, and the third via having a width greater than a width of the second via;
forming a first trace beneath and coupled to the second via, and a second trace beneath and coupled to the third via, the second trace laterally spaced apart from the first trace;
forming a fourth via beneath and coupled to the first trace, wherein the fourth via is not vertically overlapping with the second via;
forming a fifth via beneath and coupled to the second trace, wherein the fifth via is vertically overlapping with the third via;
coupling a first integrated circuit (IC) die the top side of the bridge component and to the first via, the first IC die vertically over the bridge component and the first via, and the first IC die having a first thickness;
coupling a second IC die to the top side of the bridge component, the second IC die vertically over the bridge component and laterally spaced apart from the first IC die, and the second IC die having a second thickness less than the first thickness; and
forming an encapsulant over the second IC die.

15. The method of claim 14, wherein the encapsulant is between the second IC die and the first IC die.

16. The method of claim 14, wherein the encapsulant is over the first IC die.

17. The method of claim 14, wherein the encapsulant is along sides of the first IC die.

18. The method of claim 14, wherein first via has a bottom surface at a level above the bottom side of the bridge component.

19. The method of claim 14, further comprising:
forming a sixth via vertically between the first via and the third via.

20. The method of claim 14, further comprising:
Forming a sixth via laterally between the first via and the bridge component.
